(19) United States
(12) Patent Application Publication
(10) Pub. No.: US 2011/0042793 A1
(43) Pub. Date: Feb. 24, 2011

(54) LEAD FRAME ASSEMBLY FOR A SEMICONDUCTOR PACKAGE

(75) Inventors: Kai Man WONG, Hong Kong (CN); Kam Fai LEE, Hong Kong (CN); Ho Wang WONG, Hong Kong (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC, Austin, TX (US)

(21) Appl. No.: 12/545,075

(22) Filed: Aug. 21, 2009

(51) Int. Cl. H01L 23/495; H01L 21/60

(52) U.S. Cl. 257/676; 438/123; 257/E23.037; 257/E21.506

(57) ABSTRACT

A lead frame assembly includes a first lead frame panel having a die receiving area for receiving a semiconductor die, the die having an upper surface having one or more die bond pads located thereon. A second lead frame panel includes integral leads, each integral lead including a terminal, a connecting element extending from the terminal, and a shaped contact located at an end of the connecting element. The second lead frame panel is adapted to be stacked on the first lead frame panel to position each terminal laterally of a respective die receiving area. The positioning of the terminals locates each shaped contact for contact with a respective die bond pad to establish an electrical connection between the die bond pad and the respective terminal when the semiconductor die is mounted on the respective die receiving area.

### BACKGROUND OF THE INVENTION

The present invention relates to the field of semiconductor packaging and in particular to lead frames for semiconductor packages.

Semiconductor packages use lead frames to position leads of a semiconductor package in a correct positional relationship with a semiconductor die and allow electrical connections to be formed between bond pads of the semiconductor die and respective leads. Typical lead frames include a formation of leads that are selectively connected to the bond pads of the semiconductor die using wire bonds. Existing processes for making electrical connections between the die pads and the leads typically involve a wire bonding process in which fine gold or aluminium wires are individually connected between a bond pad and a respective lead. Such a wire bonding process often also entails a further bonding process, such as a gold ball bonding process.

Existing wire bonding processes involve expensive and sophisticated equipment and increase the production time of a semiconductor device. Accordingly, there is a need for a more cost-effective technique for making electrical connections between the die pads and the leads.

### BRIEF DESCRIPTION OF THE DRAWINGS

The present invention will now be described in relation to preferred embodiments as illustrated in the accompanying drawings. However, it is to be understood that the following description is not to limit the generality of the above description.

FIG. 1 is an exploded isometric view of a lead frame assembly including a first lead frame and a second lead frame in accordance with an embodiment of the present invention;

FIG. 2 is an enlarged isometric view of a region of the first lead frame of FIG. 1 taken within the rectangle A-A;

FIG. 3 is an enlarged isometric view of a region of the second lead frame of FIG. 1 taken within the rectangle B-B;

FIG. 4 is an enlarged isometric view of a region of the second lead frame as shown in FIG. 3 taken within the rectangle C-C;

FIG. 5A shows an example of aligning the first lead frame and the second lead frame of FIG. 1 for stacking;

FIG. 5B is an enlarged isometric view of a region of the first lead frame and the second lead frame shown in FIG. 5A taken within the rectangle D-D after stacking the first and second lead frames;

FIG. 6 is an enlarged isometric view of a semiconductor package singulated from the lead frame assembly shown in FIG. 5;

FIG. 7 is an enlarged isometric side view of the structure shown in FIG. 6 viewed along the line E-E of FIG. 6;

FIG. 8 is an enlarged isometric side view of a connecting element suitable for incorporating in the second lead frame of FIG. 2, in accordance with an alternative embodiment of the present invention; and

FIG. 9 is a enlarged isometric side view of a connecting element suitable for incorporating in the second lead frame of FIG. 2 in accordance with another alternative embodiment of the present invention.

### DETAILED DESCRIPTION OF THE INVENTION

The present invention provides a lead frame assembly for a semiconductor package. The lead frame assembly includes a first lead frame including a die receiving area for receiving a semiconductor die for mounting thereon, the semiconductor die including an upper surface having one or more die bond pads located thereon; a second lead frame including plural integral leads, each integral lead including a terminal, a connecting element extending from the terminal, and a shaped contact located at an end of the connecting element.

The second lead frame is adapted for locating on the first lead frame to position each terminal laterally of a respective die receiving area. The positioning of the terminals locates each shaped contact for contact with a respective die bond pad to establish an electrical connection between the die bond pad and the respective terminal when the semiconductor die is mounted on the respective die receiving area.

Providing a lead frame that includes integral leads for establishing an electrical connection between die bond pads of the semiconductor die and respective terminals may permit a semiconductor package to be assembled in a shorter production time due to a reduction in the number of wire bonding operations which may otherwise be necessary.

The electrical connection between die bond pads of the semiconductor die and respective terminals may be a solderless connection.

Each shaped contact may include a downwardly depending surface which depends towards the die bond pad. In an embodiment, the downwardly depending surface includes a convex surface in the form of an arc. The arc may subtend a central angle of between about 45° and 90°.

In an embodiment of the invention, each connecting element includes a first section slanting upwardly from an inner edge of the terminal, and a second section extending from the first section to the shaped contact. It is preferred that the first section and the second section are arranged to form a bend therebetween that is adapted to align the second section in a parallel relationship with the upper surface of the semiconductor die. In an embodiment of the invention, the second section is adapted to overly the upper surface of the semiconductor die in a substantially parallel relationship therewith.

The first section and the second section of each connecting element may comprise respective elongate sections such as a bar or rod section having a substantially constant cross sectional area orthogonal to the longitudinal axis thereof. In another embodiment, the first section and second section of each connecting element may comprise panel or sheet like sections including a planar upper surface, a planar lower surface and elongate opposite sidewalls. In either embodiment, the longitudinal axis of the first section will intersect the longitudinal axis of the second section to form an obtuse angle at the bend.

Irrespective of the configuration of the connecting elements, it is preferred that each connecting element be adapted to resiliently bias the one or more shaped contacts to exert a contact pressure on the respective die bond pad when the lead frame assembly is assembled with the semiconductor die interposed between the first lead frame and the second lead frame.

In an embodiment of the invention, the connecting elements are resilient elements that establish the contact pressure by resiliently flexing during assembly of the lead frame assembly. In an embodiment, the resilient flexing of each connecting element occurs as the respective shaped contact bears against the respective die bond pad during an assembly process which entails the first lead frame and the second lead frame being assembled in a stacked arrangement with the semiconductor die interposed therebetween.

The present invention also provides a semiconductor package including a semiconductor die having an upper surface with one or more die bond pads located thereon; a first lead frame including a die receiving area affixed to an underside surface of semiconductor die; and a second lead frame located on the first lead frame. The second lead frame includes plural integral leads. Each integral lead includes a terminal positioned laterally of the die receiving area, a connecting element extending from the terminal, and a shaped contact located at an end of the connecting element. Each shaped contact contacts a respective die bond pad to establish an electrical connection between the die bond pad and the respective terminal.

The present invention also provides a method of forming a semiconductor package, comprising: providing a first lead frame including a die receiving area for receiving a semiconductor die for mounting thereon, the semiconductor die including an upper surface having one or more die bond pads located thereon; mounting the semiconductor die to the die receiving area; providing a second lead frame including plural integral leads, each integral lead including a terminal, a connecting element extending from the terminal, and a shaped contact located at an end of the connecting element; and locating the second lead frame on the first lead frame so that the terminals are positioned laterally of the die receiving area, and wherein each shaped contact is positioned to contact a respective die bond pad to establish an electrical connection between the die bond pad and the respective terminal.

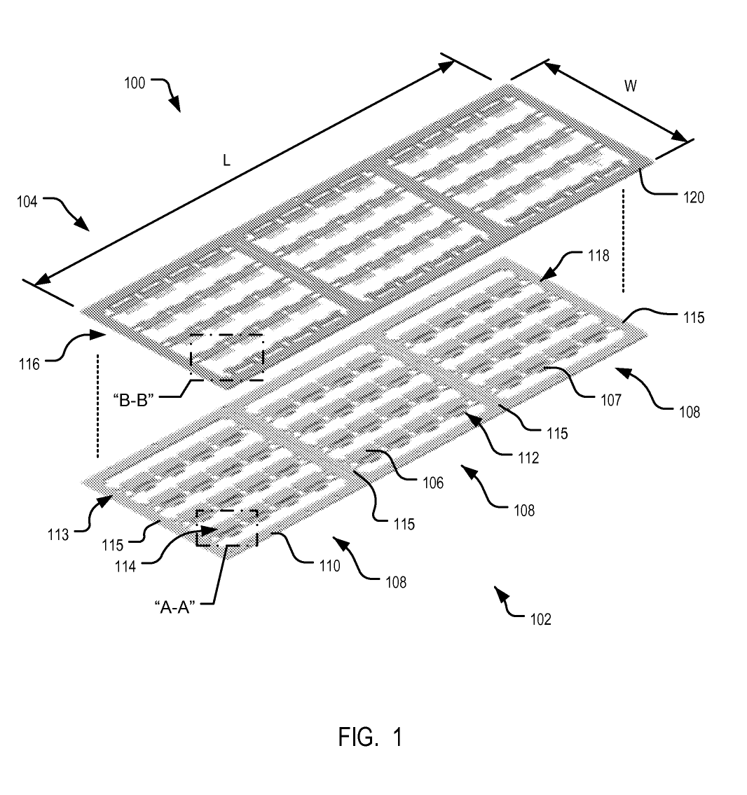

Referring initially to FIG. 1 there is shown a lead frame assembly 100 according to an embodiment of the present invention. FIG. 1 illustrates the lead frame assembly 100 prior to assembly to assist with the explanation that follows.

The lead frame assembly 100 comprises a first lead frame panel 102 (shown as the lower lead frame panel) and a second lead frame panel 104 (shown as the upper lead frame panel). It is preferred that the first lead frame panel 102 be manufactured from a single sheet of material having a high electrical conductivity as well as a high thermal conductivity (that is, a low thermal resistance) to assist with heat dissipation during operation of the semiconductor device. A suitable material for the first lead frame panel 102 is a copper alloy such as C151 H with a sheet thickness of 20 mils (1 mil is 0.001 inch). The second lead frame panel 104 may be made of the same material as the first lead frame panel 102 or a different material having high electrical conductivity. However, since the thermal conductivity of the second lead frame panel is of lesser importance, a lower thermal conductivity material may be used. A suitable base material for the second lead frame panel 104 is a copper alloy such as C194 1/2H having a sheet thickness of 5 mils.

The width and length of the first lead frame panel 102 and the second lead frame panel 104 are substantially the same. In this example, the length (L) of each lead frame panel 102, 104 is 202 mm and the width (W) is 63 mm. It will of course be appreciated that the first and second lead frame panels 102 and 104 may have any suitable dimensions.

The first and second lead frame panels 102 and 104 may be manufactured using processes that are well understood by those of skill in the art, such as chemical etching, stamping, or punching. An example of a suitable process will be described in more detail below.

The first lead frame panel 102 includes plural first die receiving areas 106 arranged in plural separate arrays 108. Each first die receiving area 106 is adapted to receive a semiconductor die for mounting thereto.

In the illustrated embodiment the first lead frame panel 102 includes three arrays 108, but it is of course possible that other embodiments may include a different number of arrays 108. The first lead frame panel 102 also includes plural second die receiving areas 107, which are smaller in area than the first die receiving areas 106. Further differences between the first die receiving areas 106 and the second die receiving areas 107 will be described later. However, the second die receiving areas 107 are not essential in the context of the present invention.

As shown in FIG. 1, each separate array 108 comprises a 4×4 arrangement of positions 112. In the embodiment illustrated one of the plural first die receiving areas 106 and one of the plural second die receiving areas 107 are located at each position 112 in an array 108. However, since the second die receiving areas 107 are not essential it will be appreciated that it is also not essential that each position 112 include a second die receiving areas 107. However, it is possible that each position 112 may include two or more die receiving areas 106. It will also be appreciated that the number of die receiving areas 106 included within each array 108, and thus the number of positions 112 provided in an array 108 will vary according to the size of the semiconductor die to be mounted on and affixed to the die receiving areas 106.

A frame 110 supports the first and second die receiving areas 106, 107 of each array 108 in plural spaced apart rows 113, with each row 113 comprising interlinked first die receiving areas 106 and interlinked second die receiving areas 107. In other words, each row 113 comprises an interlinked arrangement of first die receiving areas 106 and an associated interlinked arrangement of second die receiving areas 106.

Each row 113 extends between, and is thus supported, by a respective pair of spaced apart frame sections 115 of the frame 110. It will of course be appreciated that other configurations may also be used.

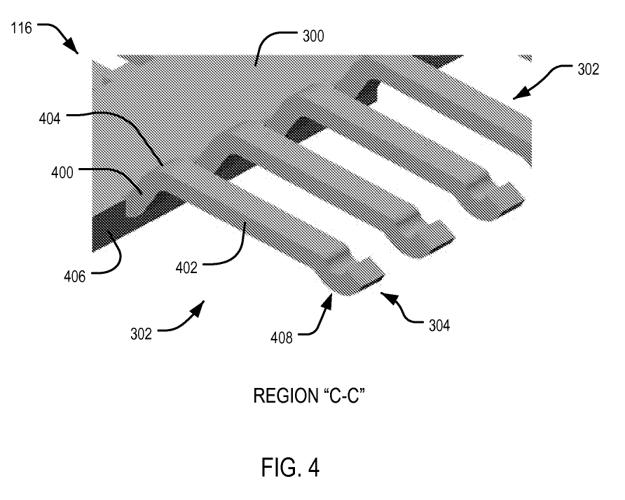

As shown in FIG. 1, the spaced apart arrangement of the plural rows 113 of an array 108 forms plural slots 118 or elongate voids between each of the adjacent rows 113 of an array 108, and also between the frame 110 and the upper and lower rows 113 of an array 108. As will be explained in more detail later, each slot 118 or elongate void is sized to accommodate terminals 300 (ref. FIG. 4) of the second lead frame panel 104 laterally adjacent to the respective first die receiving areas 106 during a stacking process in which the first and second lead frame panels 102 and 104 are “stacked”. The stacking process establishes an electrical connection between die bond pads of a semiconductor die 200 and a respective terminal 300 by interposing the semiconductor die 200 between connecting elements 302 (ref. FIG. 7) that extend from the terminals 300, and the first die receiving areas 106 of the first lead frame panel 102. An example of a suitable stacking process will be described in more detail later.

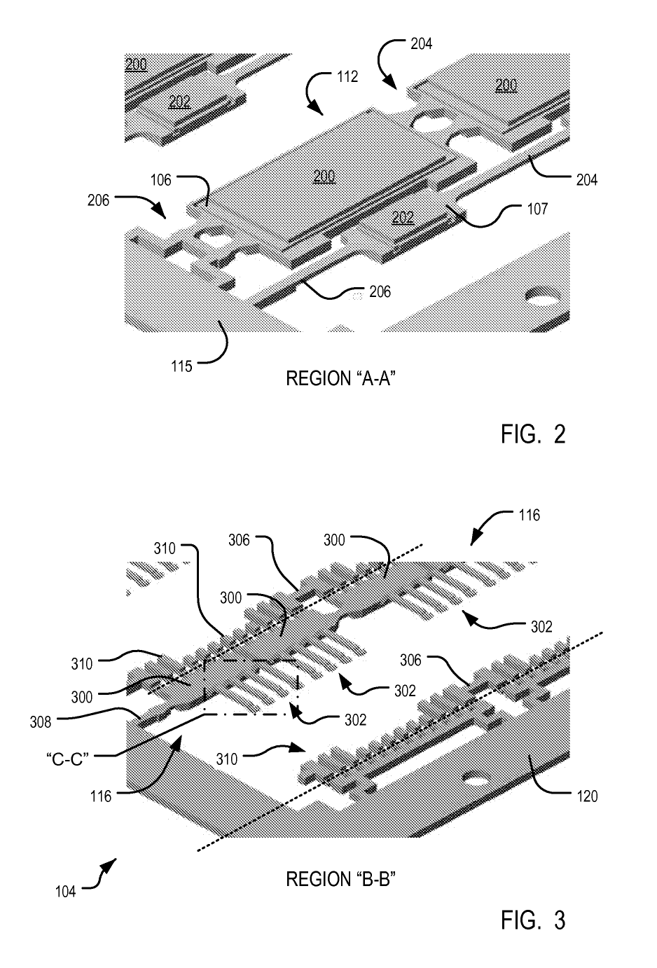

Referring now to FIG. 2 an enlarged view of the region “A-A” shown in FIG. 1 with semiconductor dies 200 and 202 mounted on respective receiving areas 106, 107 is shown. As illustrated, each die receiving area 106, 107 has a suitable size and shape for receiving the respective semiconductor die 200, 202 so that an entire underside surface 702 (ref. FIG. 7) of the semiconductor die 200, 202 contacts the respective receiving area 106, 107 for affixing thereto. In the present example, the first die receiving areas 106 are 4 mm×7 mm and the second die receiving areas are 2 mm×4 mm. Suitable processes for affixing the semiconductor dies 200, 202 to the respective receiving areas 106, 107 are well known to those of skill in the art.

In FIG. 2 the first die receiving areas 106 are each illustrated as a planar, generally rectangular area suitable for similarly shaped semiconductor die mounted thereon to be affixed thereto. It will be appreciated that the first die receiving area 106 may have other shapes depending on the shape of the semiconductor die 200. However, it is preferred that the frame 110 and the first die receiving areas 106 have coplanar upper surfaces so that the upper surfaces of the frame 110 and the first die receiving areas 106 are vertically offset from the upper surface of the semiconductor die 200 to the same extent.

Continuing now with reference to FIG. 2, in each row 113 link bars 204 extend between opposing side walls of adjacently positioned first die receiving areas 106, and also between opposing side walls of adjacently positioned die receiving areas 107. End bars 206 extend between side walls of the frame sections 115 and the side wall of the die receiving areas 106, 107 located nearest to the frame sections 115. The link bars 204 mechanically link adjacently positioned die receiving areas 106, 107 of each row 113 to form an interlinked arrangement. On the other hand, the end bars 206 mechanically link the interlinked arrangements to the frame sections 115 located adjacent the opposite ends of the interlinked arrangement and provide mechanical support of the interlinked arrangement therebetween. The link bars 204 and the end bars 206 are cut during singulation using a suitable singulation process.

Referring back to FIG. 1, the second lead frame panel 104 includes plural sets of integral leads 116. Each set of integral leads 116 is supported by a second frame 120 for alignment with an associated die receiving area 106 of the first lead frame panel 102 during the stacking process. In this respect, references to the term “integral lead” throughout this specification denote a lead that is integral with the second lead frame panel 104 and that is adapted to contact one or more die bond pads of a semiconductor die to establish an electrical connection between the second lead frame panel 104 and the die bond pad. Each integral lead is thus “preformed” prior to stacking the first and second lead frame panels 102 and 104 to form the completed lead frame assembly 100.

FIG. 3 is an enlarged view of the region “B-B” shown in FIG. 1 illustrating the integral leads 116 in more detail. As is shown in FIG. 3, terminals 300 are arranged in rows of interlinked arrangements that are interconnected by link bars 306 and attached to the frame 120 by end link bars 308. The link bars 306 and end link bars 308 are cut during singulation of the semiconductor package.

FIG. 3 also depicts lead elements 310 that are adapted for connection to die bond pads of the semiconductor dies 200, 202 via conventional interconnection processes involving wire bonding. The lead elements 310 are arranged in rows that are cut along a half etched channel (shown as a dashed lines in FIG. 3) during singulation to separate individual lead elements 310 from either the terminals 300 or the second frame 120.

FIG. 4 illustrates the region “C-C” shown in FIG. 3 to show the geometry of the connecting elements 302 in more detail.

As shown in FIG. 4, each integral lead 116 includes the terminal 300 and plural connecting elements 302 extending from the terminal 300. It is not essential that each integral lead 116 include plural connecting elements 302 since it is possible that in some embodiments a single connecting element 302 may be suitable. The number of connecting elements 302 for each terminal 300 may vary, for example, according to desired electrical current to be conducted via the terminal 300 and geometric properties that affect the current carrying capacity of a connecting element 302, such as the cross-sectional area of the connecting elements 302.

In the present case each of the plural connecting elements 302 has the same length, which is about 3 mm. However, the length of the connecting elements 302 may vary according to the location of the semiconductor die pads. Thus, it is possible that each of the plural connecting elements 303 may have different respective lengths. As is illustrated, each connecting element 302 includes a first section 400 and a second section 402.

The first section 400 is an elongate section that slants upwardly from an inner wall 406 of the terminal 300 and extends to a bend 404. An embodiment in which the first section 400 extends from the inner wall 406 of the terminal 300 is advantageous because in such an arrangement the first section 400 does not increase the overall height of the terminal 300 and thus does not increase the overall vertical profile of the terminal 300. However, it is possible that the first section 400 may extend from the top surface of the terminal 300.

The second section 402, which is also an elongate section, extends generally horizontally from the bend 404 to a shaped contact 304. Thus, in the embodiment illustrated, the first and second sections 400 and 402 have respective longitudinal axes that intersect to form an oblique intersection angle therebetween at the bend 404.

The shaped contact 304 preferably includes a downwardly depending surface 408. In the embodiment illustrated, the downwardly depending surface 408 includes a convex surface in the form of an arc subtending about 90 degrees. A convex surface is preferred for ease of manufacture by conventional manufacturing techniques. However, it is possible that other downwardly depending surfaces may be used.

The above described arrangement of the first and second sections 400 and 402 of the connecting elements 302 establishes a vertical offset between the lower most part of the downwardly depending surface 408 and an underside surface 704 (ref. FIG. 7) of the terminal 300 and thus the die receiving area 106.

The first and second sections 400 and 402 are arranged so that the extent of the vertical offset is sufficient to cause the lowermost part of the downwardly depending surface 408 to resiliently contact a die bond pad of the semiconductor die 200 when the semiconductor die 200 is interposed between the first and second lead frame panels 102 and 104. When so interposed, the height of the upper surface 700 of the semiconductor die 200 relative to the underside surface 702 (ref. FIG. 7) of the die receiving area 106 exceeds the vertical offset between the lowermost part of the downwardly depending surface 408 and the underside surface 704 (ref. FIG. 7) of the terminal 300, thus causing the lowermost part of the downwardly depending surface 408 to bear against the respective die bond pad.

Thus, following assembly of the lead frame assembly 100 by way of a “stacking” process, each shaped contact 304 resiliently contacts a respective die bond pad of the semiconductor die 200 to form an electrical connection between the die bond pad of the semiconductor die 200 (ref. FIG. 2) and the terminal 300. In other words, the shaped contact 304 is adapted to contact a respective die bond pad of the semiconductor die 200 to establish an electrical connection between the die bond pad and the terminal 300 when the semiconductor die 200 is interposed between the first lead frame panel 102 and second lead frame panel 104.

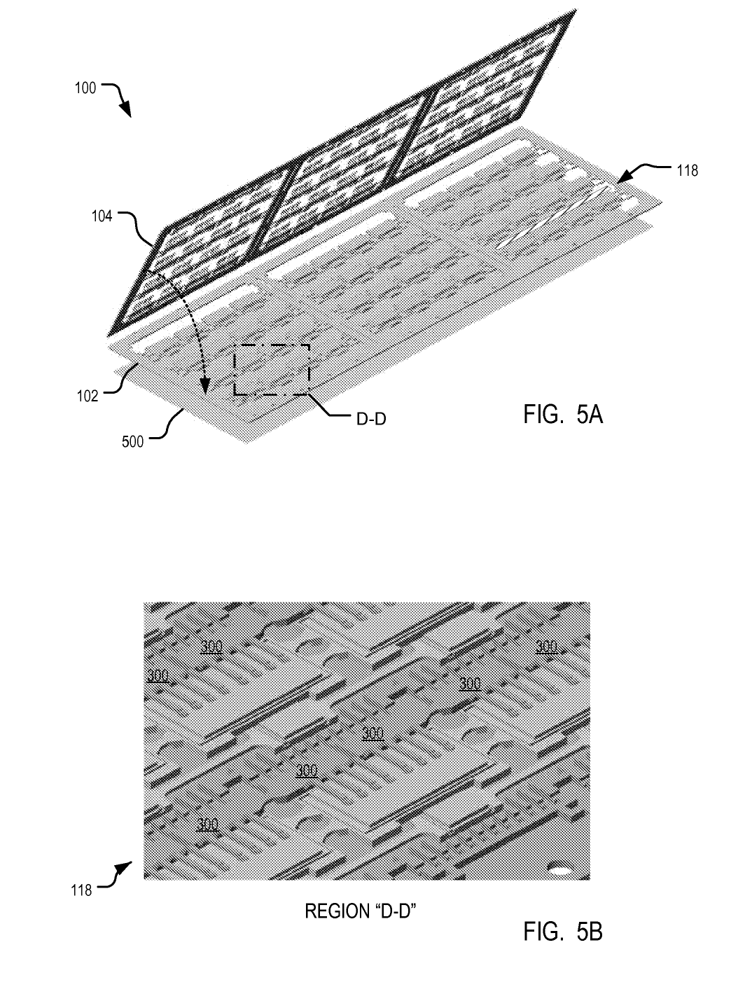

FIG. 5A shows an example of aligning the first lead frame panel 102 and the second lead frame panel 104 for stacking. FIG. 5B illustrates an enlarged view of region “D-D” shown in FIG. 5A after stacking of the lead frame panels.

Turning now to FIGS. 5A and 5B, the stacking process involves aligning the first and second lead frame panels 102 and 104, and pressing the first and second lead frame panels 102 and 104 onto a substrate 500. When aligned and pressed together in this way the terminals 300 (ref. FIG. 5B) of the second lead frame panel 104 are accommodated in the slots 118 or elongate voids (one of which is shown in FIG. 5A as a hatched region) between each of the adjacent rows 113 (ref. FIG. 1) of the die receiving areas 106 in each array 108, and also between the frame 110 and the upper and lowermost rows 113 of an array 108.

As shown in FIG. 7, following stacking, the terminals 300 are located so that the underside surface 704 of each terminal 300 sits on the substrate 500 in a coplanar relationship with the underside surface 702 of each die receiving area 106.

The substrate 500 includes a bonding layer which adheres to respective underside surfaces 702, 704 of the terminals 300 and the die receiving areas 106 respectively to thereby secure the positions of the first and second lead frame panels 102 and 104. In the present case, the substrate 500 is a polyimide adhesive film having a typical thickness of about 30 μm. The polyimide adhesive film is removed after a singulation process in which individual semiconductor packages are formed.

Affixing the first and second lead frame panels 102 and 104 to the substrate 500 reduces resin or mold compound bleeding during a subsequent molding or encapsulation process on the underside surfaces of the first and second lead frame panels 102 and 104.

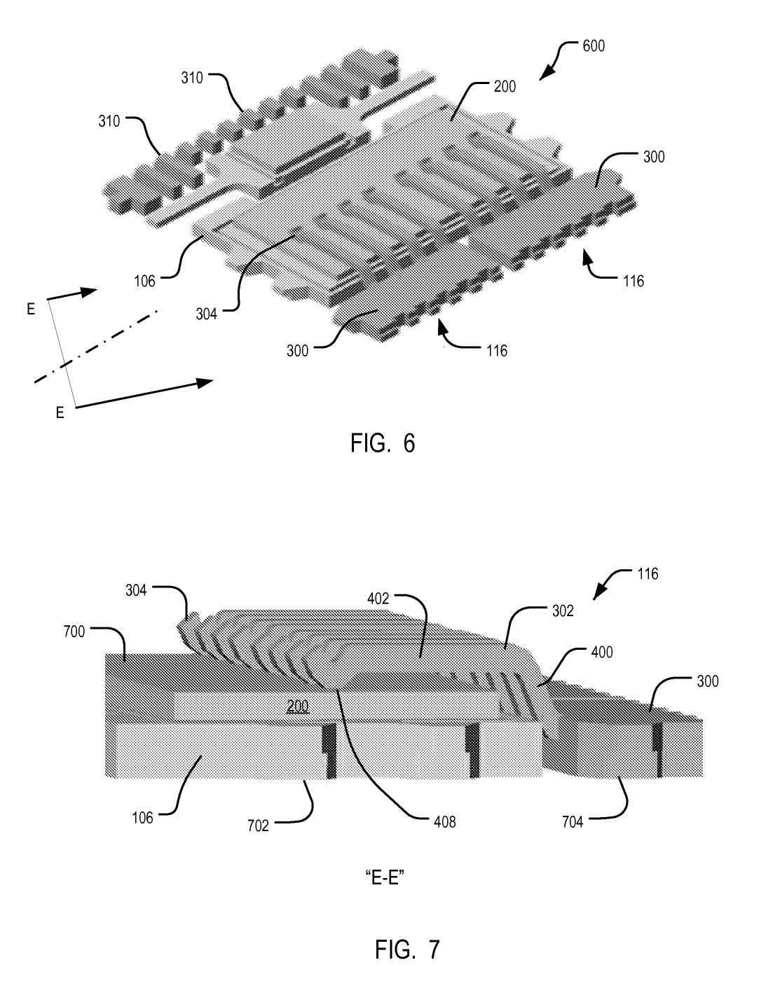

FIG. 6 shows a semiconductor package after singulation but without the mold compound or encapsulant and without wire interconnections between the lead elements 310 and die bond pads, for clarity. Referring now to FIGS. 6 and 7, stacking the first and second lead frame panels 102 and 104 places the shaped contact 304 of each integral lead 116 in electrical contact with a respective die bond pad (not shown) of a semiconductor die 200.

As described earlier, due to the relative positional relationship between the lowermost part of the downwardly depending surface 408 and the upper surface of the semiconductor die 200, after stacking, the shaped contact 304 is resiliently biased to exert a contacting pressure on the die bond pad. That is to say, the stacking process mechanically loads the connecting element 302 to create a “spring back effect” that causes the shaped contact 304 to be urged against the die bond pad.

In the present case, the connecting elements 302 are adapted to flex resiliently as the first and second lead frame panels 102 and 104 are stacked together. The resilient flexing of the connecting elements 302 during the stacking process arises from the mechanical interaction described earlier between the die bond pad and the respective shaped contact 304 of the connecting element 302 when the die bond pad and the respective shaped contact 304 are pressed together.

As shown in FIG. 7, when the first and second lead frame panels 102 and 104 are stacked with the semiconductor die 200 interposed therebetween, the second section 402 overlies and is spaced apart from the upper surface 700 of the semiconductor die 200, and has a substantially parallel relationship therewith. Providing the spacing between upper surface 700 of the semiconductor die 200 and the second section 402 prevents undesirable contact between the second section 402 and regions of the die upper surface 700 outside of the die bond pad, and thus prevents unintended electrical connections from being formed therebetween.

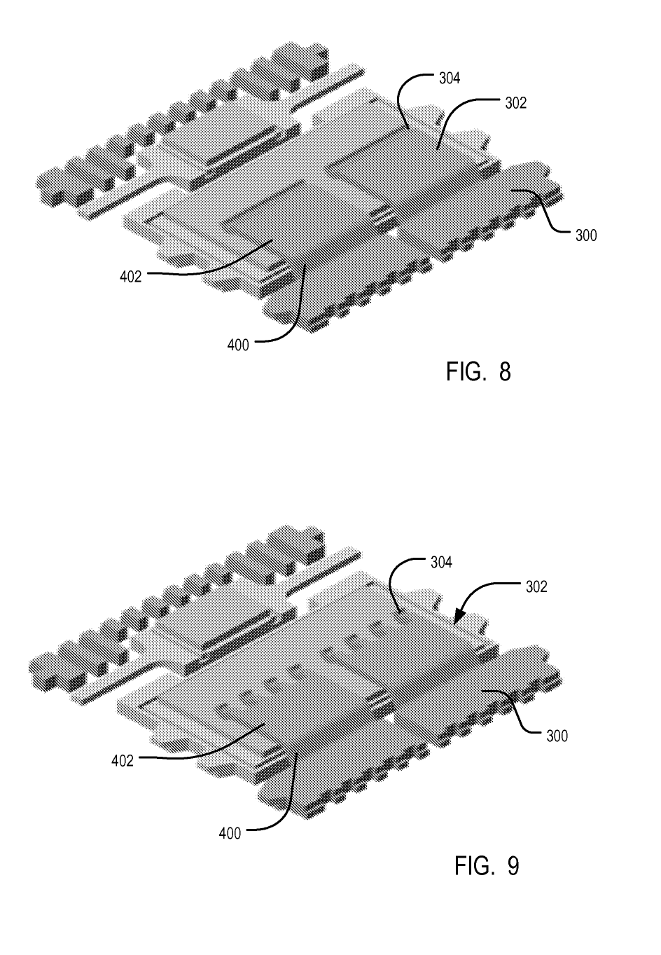

FIGS. 8 and 9 illustrate alternative embodiments in which the connecting element 302 has a different mechanical configuration from the embodiment described earlier. In the embodiment depicted in FIG. 8, each connecting element 302 includes a planar first section 400, a planar second section 402, and a shaped contact 304 that extends along the entire width of the connecting element 302. The embodiment depicted in FIG. 9 is similar to that of FIG. 8 in that each connecting element 302 includes planar first and second sections 400 and 402. However, in this embodiment each connecting element 302 includes plural shaped contacts 304 that are arranged along the width of the connecting element 302.

In terms of manufacturing the first and second lead frame panels 102 and 104, various processes may be used. One example of a suitable process involves a chemical etching process in which a photoresist is laminated on both sides of a raw copper frame. A photomask with a specified lead frame pattern is then used for photoresist exposure. The lead frame pattern is coated by the photoresist after development and the unnecessary part is chemically etched. The photoresist is then removed after the etching process. The shape and bend of connecting elements 302 may then formed by a suitable mechanical stamping process. A Ni—Pd—Au layer is then plated on the lead frame surfaces to provide protection during a subsequent molding process. The Ni—Pd—Au layer also is suitable for soldering during surface mount processes. Finally, the lead frame is separated into strip form for a further assembly process. The process parameters and etching time may be different between the first lead frame panel 102 and second lead frame panel 104 due to different unit pattern and frame thickness.

As is evident from the foregoing discussion, the present invention provides a lead frame assembly, and a method of packaging a semiconductor package which has benefits over existing products and processes. For example, by providing integral connecting elements the present invention is able to reduce the number of wire bonding type interconnection operations required during the assembly process.

The description of the preferred embodiments of the present invention have been presented for purposes of illustration and description, but are not intended to be exhaustive or to limit the invention to the forms disclosed. It will be appreciated by those skilled in the art that changes could be made to the embodiments described without departing from the broad inventive concept thereof. It is to be understood, therefore, that this invention is not limited to the particular embodiments disclosed, but covers modifications within the spirit and scope of the present invention.

1. A lead frame assembly for a semiconductor package,
the lead frame assembly comprising:
a first lead frame panel including one or more die receiving areas for receiving a respective semiconductor die for mounting thereon, each semiconductor die including an upper surface having one or more die bond pads located thereon; and
a second lead frame panel including plural integral leads, each integral lead including a terminal, a connecting element extending from the terminal, and a shaped contact located at an end of the connecting element;
wherein the second lead frame is adapted for locating on the first lead frame to position each terminal laterally of a respective die receiving area, said positioning locating each shaped contact for contact with a respective die bond pad to establish an electrical connection between the die bond pad and the respective terminal when the semiconductor die is mounted on the respective die receiving area.

2. A lead frame assembly according to claim 1, wherein each shaped contact includes a downwardly depending surface.

3. A lead frame assembly according to claim 2, wherein the downwardly depending surface includes a convex surface in the form of an arc subtending a central angle of between about 45° and 90°.

4. A lead frame assembly according to claim 1, wherein each connecting element includes:
a first section slanting upwardly from an inner edge of the terminal and terminating at a bend; and
a second section extending from the bend to the shaped contact.

5. A lead frame assembly according to claim 4, wherein the first section and the second section include elongate sections having respective longitudinal axes that intersect to form an oblique intersection angle therebetween at the bend.

6. A lead frame assembly according to claim 5, wherein the first section, the second section and the bend are adapted to provide a predetermined vertical offset between a lowermost part of the downwardly depending surface relative to the die receiving area when the second lead frame panel is located on the first lead frame panel.

7. A lead frame assembly according to claim 6, wherein each connecting element is adapted to resiliently bias the shaped contact to exert a contacting pressure on the respective die bond when the semiconductor die is mounted on the respective die receiving area and the second lead frame panel is located on the first lead frame panel so as to interpose the semiconductor die therebetween.

8. A lead frame assembly according to claim 4, wherein the first section and the second section include planar sections having respective longitudinal axes that intersect to form an oblique intersection angle therebetween at the bend.

9. A lead frame assembly according to claim 8, wherein the first section, the second section and the bend are adapted to provide a predetermined vertical offset between a lowermost part of the downwardly depending surface relative to the die receiving area when the second lead frame panel is located on the first lead frame panel.

10. A lead frame assembly according to claim 9, wherein each connecting element is adapted to resiliently bias the shaped contact to exert a contacting pressure on the respective die bond pad when the semiconductor die is mounted on the respective die receiving area and the second lead frame panel is located on the first lead frame panel so as to interpose the semiconductor die therebetween.

11. A lead frame assembly according to claim 1, wherein each integral lead includes a plurality of shaped contacts located at the end of the connecting element, said plurality of shaped contacts being spaced apart across the width of the connecting element.

12. A lead frame assembly according to claim 1, wherein the electrical connection between the die bond pad and the respective terminal is a solderless connection.

13. A semiconductor package, comprising:
a semiconductor die including an upper surface having one or more die bond pads located thereon;
a first lead frame panel including a die receiving area affixed to an underside surface of semiconductor die; and
a second lead frame panel located on the first lead frame panel, the second lead frame including plural integral leads, each integral lead including a terminal positioned laterally of the die receiving area, a connecting element extending from the terminal, and a shaped contact located at an end of the connecting element;
wherein each shaped contact contacts a respective die bond pad to establish an electrical connection between the die bond pad and the respective terminal.

14. The semiconductor package of claim 13, wherein each connecting element resiliently biases the shaped contact to exert a contacting pressure on the respective die bond pad.

15. The semiconductor package of claim 13, wherein each integral lead includes a plurality of shaped contacts located at the end of the connecting element, said plurality of shaped contacts being spaced apart across the width of the connecting element.

16. The semiconductor package of claim 13, wherein the electrical connection between the die bond pad and the respective terminal is a solderless connection.

17. A method of forming a semiconductor package, comprising:
providing a first lead frame panel including a die receiving area for receiving a semiconductor die for mounting thereon, the semiconductor die including an upper surface having one or more die bond pads located thereon;
mounting the semiconductor die to the die receiving area;
providing a second lead frame panel including plural integral leads, each integral lead including a terminal, a connecting element extending from the terminal, and a shaped contact located at an end of the connecting element; and
locating the second lead frame panel on the first lead frame panel to position each terminal laterally of the die receiving area, and wherein each shaped contact is positioned to contact a respective die bond pad to establish an electrical connection between the die bond pad and the respective terminal.

18. The method of forming a semiconductor package of claim 17, wherein locating the second lead frame panel on the first lead frame panel resiliently biases the shaped contact to exert a contacting pressure on the respective die bond pad of the semiconductor die.

19. The method of forming a semiconductor package of claim 17, wherein each integral lead includes a plurality of shaped contacts located at the end of the connecting element, said plurality of shaped contacts being spaced apart across the width of the connecting element.
